(19) United States
(12) Patent Application Publication
(10) Pub. No.: US 2015/0349208 A1
(43) Pub. Date: Dec. 3, 2015

(54) LIGHT EMITTING DEVICE AND METHOD FOR FABRICATING THE SAME

(71) Applicant: Electronics and Telecommunications Research Institute, Daejeon (KR)

(72) Inventors: Dong Churl KIM, Daejeon (KR); Sung Bock KIM, Daejeon (KR); Jong Bae KIM, Daejeon (KR); Ju Hee BAEK, Daejeon (KR)

(73) Assignee: Electronics and Telecommunications Research Institute, Daejeon (KR)

(21) Appl. No.: 14/596,253

(22) Filed: Jan. 14, 2015

(30) Foreign Application Priority Data
May 30, 2014 (KR) 10-2014-0066119

(51) Int. Cl. H01L 33/40; H01L 33/20; H01L 33/46

(52) U.S. Cl. CPC H01L 33/405; H01L 33/46; H01L 33/20; H01L 2933/0016; H01L 2933/0025

(57) ABSTRACT

Provided herein is a semiconductor light emitting device capable of increasing the light extraction efficiency and a fabricating method thereof, the device including a buffer layer formed on a substrate; an n-type semiconductor layer formed on the buffer; an active layer formed on a partial area of the n-type semiconductor layer such that the n-type semiconductor layer is exposed; a p-type semiconductor layer formed on the active layer; a transparent conductive layer formed on the p-type semiconductor layer; a first mesa surface formed along a side wall of the active layer from a side wall of the transparent conductive layer; a passivation layer formed along the first mesa surface; and a metal reflectance film formed along the passivation layer such that it re-reflects escaping light, thereby re-reflecting escaping light to increase the light extraction efficiency.

### CROSS-REFERENCE TO RELATED APPLICATION

The present application claims priority to Korean patent application number 10-2014-0066119, filed on May 30, 2014, the entire disclosure of which is incorporated herein in its entirety by reference.

### BACKGROUND

1. Field of Invention

Various embodiments of the present invention relate to a light emitting device and a method for fabricating the same, and more particularly, to a light emitting device capable of increasing the light extraction efficiency, and a fabricating method thereof.

2. Description of Related Art

An LED (Light Emitting Device) has been in the limelight recently, and is thus being widely used for treatments besides lighting. Replacing a conventional incandescent lamp with an LED increases the light conversion efficiency with less electricity, and thus it is advantageous for saving energy. Since the development of GaN-type blue LEDs, the LED industry has grown remarkably, and numerous studies have been conducted.

For GaN-type LEDs, various techniques have been studied aimed at obtaining more light energy. When using a patterned sapphire substrate, the light directed towards the substrate tend to scatter in various directions, thereby reducing the amount of total reflection from the surface where the light is emitted and increasing the light extraction efficiency.

Similar ways to reduce the amount of total reflection from the surface where light is emitted include: making the surface of the LED coarse, forming a regular pattern on the LED surface, or forming an irregular pattern on the LED surface, thereby increasing the light extraction efficiency.

Furthermore, by etching a portion of the semiconductors that form an LED such that an n-electrode is exposed, the semiconductors may be etched to form a reverse mesa structure. LEDs formed in such a method may trap light near the active layer of the LEDs, thereby increasing the light extraction efficiency.

### SUMMARY

Various embodiments of the present invention are directed to a light emitting device that is coated with a passivation layer and a metal reflectance film on an surface that is etched for forming electrodes such that light escaping through an etched surface may be re-reflected and that escaping light may be restricted, thereby increasing the light extraction efficiency.

One embodiment of the present invention provides a light emitting device including a buffer layer formed on a substrate; an n-type semiconductor layer formed on the buffer; an active layer formed on a partial area of the n-type semiconductor layer such that the n-type semiconductor layer is exposed; a p-type semiconductor layer formed on the active layer; a transparent conductive layer formed on the p-type semiconductor layer; a first mesa surface formed along a side wall of the active layer from a side wall of the transparent conductive layer; a passivation layer formed along the first mesa surface; and a metal reflectance film formed along the passivation layer such that it re-reflects escaping light.

The first mesa surface may be formed in any one of a forward mesa shape, reverse mesa shape, and vertical mesa shape.

The buffer layer and the n-type semiconductor layer may be formed on a partial area of the substrate, and may include a side wall consisting of a second mesa surface.

The second mesa surface may be formed in any one of a forward mesa shape, reverse mesa shape, and vertical mesa shape.

The passivation layer and the metal reflectance film may be further formed along the second mesa surface.

The device may further comprise an n-electrode contacting the n-type semiconductor layer; and a p-electrode contacting the transparent conductive layer.

The n-electrode and the p-electrode are made of a same material as the metal reflectance film.

Another embodiment of the present invention provides a method for fabricating a light emitting device, the method including laminating a buffer layer, n-type semiconductor layer, active layer, p-type semiconductor layer, and transparent conductive layer on a substrate successively; forming a first mesa surface by etching the transparent conductive layer, the p-type semiconductor layer, the active layer, and a partial thickness of the n-type semiconductor layer such that the n-type semiconductor layer is exposed; forming a passivation layer along the first mesa surface; and forming a metal reflectance film configured to re-reflect escaping light along the passivation layer.

The forming a first mesa surface may be performed by a forward mesa etching process using an etching mask made of any one of a photoresist, SiO₂, and SiₓN_{y} (x,y are natural numbers).

The method may further include forming a second mesa surface by etching the n-type semiconductor layer and the buffer layer such that the substrate is exposed, wherein at the forming a passivation layer and a metal reflectance film, the passivation layer and the metal reflectance film may be further formed along the second mesa surface.

The forming a first mesa surface or the forming a second mesa surface may include forming a reverse mesa in an ICP-RIE (inductively coupled plasma-reactive ion etching) method using an etching mask made of Ni, and an etching gas including Cl₂ and Ar or an etching gas including Cl₂ and BCl₃.

The forming first mesa surface of the a second mesa surface may include forming a vertical mesa in an ICP-RIE (inductively coupled plasma-reactive ion etching) method using an etching mask made of Cr.

The method may further include forming an n-electrode contacting the n-type semiconductor layer and a p-electrode contacting the transparent conductive layer.

The forming an n-electrode and p-electrode may be performed separately from the forming of a metal reflectance film.

The forming an n-electrode and p-electrode may be performed at the same time of the forming of a metal reflectance film.

The forming a metal reflectance film, n-electrode and p-electrode may include forming a photoresist film on an upper portion of an entire structure where the passivation layer is formed; forming a photoresist pattern that opens the passivation layer, transparent conductive layer, and n-type semiconductor layer by etching the photoresist layer; and filling an area where the photoresist film is etched with a conductive material.

According to the aforementioned embodiments of the present invention, a passivation layer and a metal reflectance film are formed on a surface that is etched for forming electrodes such that light escaping through an etching surface may be re-reflected and escaping light may be restricted thereby increasing the light extraction efficiency.

### BRIEF DESCRIPTION OF THE DRAWINGS

The above and other features and advantages of the present invention will become more apparent to those of ordinary skill in the art by describing in detail exemplary embodiments with reference to the attached drawings in which:

FIG. 1 is a cross-sectional view illustrating an LED according to an embodiment of the present invention;

FIG. 2 is a cross-sectional view illustrating an LED according to another embodiment of the present invention;

FIG. 3 is a cross-sectional view illustrating an LED according to another embodiment of the present invention;

FIG. 4 is a cross-sectional view illustrating an LED according to another embodiment of the present invention;

FIG. 5 is a cross-sectional view illustrating an LED according to another embodiment of the present invention; and

FIG. 6 is a cross-sectional view illustrating an LED according to another embodiment of the present invention.

### DETAILED DESCRIPTION

The present invention will be described more fully hereinafter with reference to the accompanying drawings, in which embodiments of the invention are shown. This invention may, however, be embodied in different forms and should not be construed as limited to the embodiments set forth herein.

In this specification, a singular form may include a plural form as long as it is not specifically mentioned in a sentence. Furthermore, ‘include/comprise’ or ‘including/comprising’ used in the specification represents that one or more components, steps, operations, and elements exist or are added.

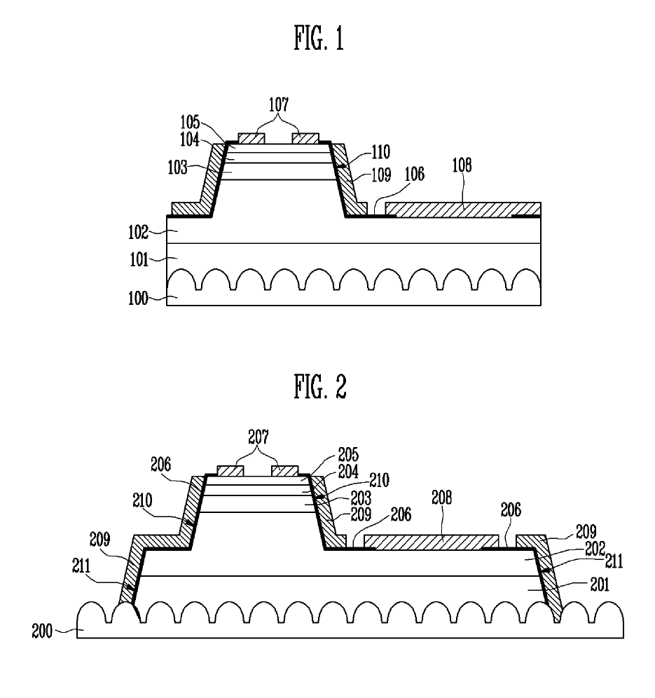

FIG. 1 is a cross-sectional view illustrating an LED according to an embodiment of the present invention.

Referring to FIG. 1, an LED includes a buffer layer 101 formed on a substrate 100, an n-type semiconductor layer 102 laminated on the buffer layer 101, an active layer 103 grown on the n-type semiconductor layer 102, a p-type semiconductor layer 104 grown on the active layer 103, and a transparent conductive layer 105 formed on the p-type semiconductor layer 104. Herein, a method for forming each layer, material for forming each layer, and thickness of each layer may be based on well-known techniques generally known in the related field.

For example, the substrate 100 may be a PSS (Patterned Sapphire Substrate). On the PSS, a high quality semiconductor layer may be grown. On the PSS, light may scatter in various directions, and thus it is possible to increase the amount of light that escapes the transparent conductive layer 105 from the substrate 100 towards the transparent conductive layer 105.

The buffer layer 101 is a semiconductor layer that may be grown on the substrate 100. The buffer layer 101 may be made of u-GaN (undoped-GaN).

The n-type semiconductor layer 102 may be an n-type GaN layer laminated on the buffer layer 101.

The active layer 103 is a semiconductor layer grown on the n-type semiconductor layer 102, and the active layer 103 may be made of any one of InGaN, AlGaN, MQW (multi-quantum well), and single quantum well structure.

The p-type semiconductor layer 104 may be a p-type GaN layer grown on the active layer 103.

The transparent conductive layer 105 may be made of, but is not limited to, TCO (Transparent Conducting Oxide) such as indium tin oxide.

After the transparent conductive layer 105 is formed, the p-type semiconductor layer 104, active layer 103, and n-type semiconductor layer 102 of a partial thickness are etched such that the n-type semiconductor layer 102 is exposed. Herein, the etching process may be an ICP-RIE (inductively coupled plasma-reactive ion etching) method, but there is no limitation thereto, and thus the etching process may be appropriately selected by one skilled in the art. The etching process is performed such that a side wall of the etched structure has a first mesa surface 110 of a forward mesa shape. As the side wall of the etched structure is formed in the forward mesa shape, the width of the etched structure gets wider as it gets to the lower portion thereof.

The first mesa surface 110 of the forward mesa shape may be formed by performing the etching process using an etching mask made of a material having a small etching selection ratio to the p-type semiconductor layer 104, active layer 103, and n-type semiconductor layer 102. For example, the etching mask may be made of a material having a small etching selection ratio to GaN, and more particularly, the etching mask may be made of any one of a photoresist, SiO₂, and SiₓN_{y} (x,y are natural numbers), or an insulation material capable of exerting a similar function as any one of the photoresist, SiO₂, and SiₓN_{y} (x,y are natural numbers). When the etching mask is made of a photoresist having an etching selection ratio to GaN of 1:1, an inclination angle of the first mesa surface may be formed to be 45°. The etching selection ratio to GaN of a material applied to the etching mask besides the aforementioned may be set to be various, and the inclination angle of the first mesa surface 110 may be changed to various inclination angles. For example, the etching selection ratio may be controlled by adjusting the thickness of the etching mask made of SiO₂, SiₓN_{y} (x,y are natural numbers), the inclination degree of the mask, and the density of the mask.

Then, a heating process for an ohmic connection of the transparent conductive layer 105 and the p-type semiconductor layer 104 may be performed.

Then, along the surface of the entire structure where the first mesa surface 110 is formed, a passivation layer 106 is laminated. SiO₂, SiNₓ (x is a natural number) may be used as the passivation layer 106. After the passivation layer 106 is laminated, a partial area of the passivation layer 106 is etched such that an upper surface of the transparent conductive layer 105 and the n-type semiconductor layer 106 are exposed. Herein, a general etching method in the field may be used, the method being selected according to the material of the passivation layer 106.

The passivation layer 106 may be used for electrical passivation. The passivation layer 106 may remain along the first mesa surface 110 to play a role of preventing an electrical short of a metal reflectance film 109 and the n-type semiconductor layer 102 and an electrical short of the metal reflectance film 109 and the p-type semiconductor layer 104 that will be explained hereinafter.

Then, a p-electrode 107 and an n-electrode 108 are formed. The p-electrode 107 comes in contact with the transparent conductive layer 105 exposed through the passivation layer 106 etching process. The n-electrode 108 comes in contact with the n-type semiconductor layer 102 exposed through the passivation layer 106 etching process. Herein, any electrode material generally known in the related field may be used, and any generally known method in the related field may be used. Then, a heating process for an ohmic contact of the n-electrode 108 may be performed.

A patterning process of the n-electrode 108 and p-electrode 107 may be performed at the same time or separately. The n-electrode 108 may be made of a material having a smaller work function than the n-type semiconductor layer 102. When the n-type semiconductor layer 102 is n-GaN, the n-electrode 108 may be formed in a multilayer structure where at least one of Ag, Nb, Ti, Al, In, Ta, and Cr, and Au for packaging pads are laminated. There is no limitation to the material of the p-electrode 107 since the transparent conductive layer 105 will form an ohmic contact with the p-electrode 107. Accordingly, the p-electrode 107 may be formed using a same material film as the n-electrode 108.

The metal reflectance film 109 is coated on the surface of the first mesa surface 110 to which the passivation layer 106 for preventing an electrical short is applied. The forward mesa shape can be helpful for the metal reflectance film 109 to be laminated on the first mesa surface 110.

The laminated thickness of the metal reflectance film 109 must be thicker than the optical skin depth of the metal reflectance film 109 regarding the wavelength of the LED. When the thickness of the metal reflectance film 109 is not thicker than the optical skin depth, there may exist fluctuations in an air area past the metal reflectance film 109, resulting in a significant magnitude of penetration ratio. The metal reflectance film 109 may be made of a metal material having a big reflectance ratio to the wavelength of the LED to be formed, for example Au, Al, and Ag. The metal reflectance film 109 may re-reflect the light escaping from the first mesa surface 110, thereby increasing the light extraction efficiency of the LED.

Herein, the metal reflectance film 109, p-electrode 107, and n-electrode 108 may be made of a same material. When the metal reflectance film 109 and the n-electrode 108 are made of a same material, the metal reflectance film 109 may be formed in a structure where at least one of Ag, Nb, Ti, Al, In, and Ta for an ohmic contact, and Au for packaging pads are laminated.

FIG. 2 is a cross-sectional view illustrating an LED according to another embodiment of the present invention.

Referring to FIG. 2, just as in FIG. 1, an LED includes a buffer layer 201 formed on a substrate 200, an n-type semiconductor layer 202 laminated on the buffer layer 201, an active layer 203 grown on the n-type semiconductor layer 202, a p-type semiconductor layer 204 grown on the active layer 203, and a transparent conductive layer 205 formed on the p-type semiconductor layer 204. The substrate 200, buffer layer 201, n-type semiconductor layer 202, active layer 203, p-type semiconductor layer 204, and transparent conductive layer 205 may be made of a same material and in a same method as described with reference to FIG. 1.

Then, as illustrated in FIG. 1, a first mesa surface 210 of a forward mesa shape is formed on a side wall of a structure etched by etching the transparent conductive layer 205, p-type semiconductor layer 204, active layer 203, and n-type semiconductor layer 202 of a partial thickness such that the n-type semiconductor layer 202 is exposed.

As illustrated in FIG. 1, the first mesa surface 210 of the forward mesa shape may be formed by performing an etching process using a first etching mask made of a material having a small etching selection ratio to the p-type semiconductor layer 204, active layer 203, and n-type semiconductor layer 202. For example, the first etching mask may be made of a material having a small etching selection ratio to GaN, and more particularly, the first etching mask may be made of any one of a photoresist, SiO₂, and SiₓN_{y} (x,y are natural numbers), or an insulation material capable of exerting a similar function as any one of the photoresist, SiO₂, and SiₓN_{y} (x,y are natural numbers). When the etching mask is made of a photoresist having an etching selection ratio to GaN of 1:1, the inclination angle of the first mesa surface 110 may be formed to be 45°. The etching selection ratio to GaN of a material applied to the etching mask besides the aforementioned may be various, and the inclination angle of the first mesa surface 110 may be changed to various inclination angles. For example, the etching selection ratio may be controlled by adjusting the thickness of the etching mask made of SiO₂, SiₓN_{y} (x,y are natural numbers), the inclination degree of the mask, and the density of the mask.

Then, the n-type semiconductor layer 202 and buffer layer 201 of a partial thickness that remain in a lower portion of the first mesa surface 210 are etched. Accordingly, the substrate may be exposed. Herein, the etching process used may be, but is not limited to, a method such as an ICP-RIE (inductively coupled plasma-reactive ion etching) method, and thus the method may be appropriately selected by one skilled in the related art. The etching process is performed such that a side wall of an etched structure has a second mesa surface 211 of a forward mesa shape. The second mesa surface 211 of the forward mesa shape may be formed using a second etching mask made of a same material as the first etching mask used in the etching process for forming the first mesa surface 210. For example, the second etching mask may be made of any one of a photoresist, SiO₂, and SiₓN_{y} (x,y are natural numbers).

Then, a heating process for an ohmic contact of the transparent conductive layer 205 and p-type semiconductor layer 204 may be performed.

Then, a passivation layer 206 is laminated along the surface of the entire structure where the first and second mesa surface 210, 211 are formed. SiO₂, SiNₓ (x is a natural number) may be used for the passivation layer 106. After the passivation layer 206 is laminated, a partial area of the passivation layer 206 is etched such that an upper surface of the transparent conductive layer 205 and the n-type semiconductor layer 206 are exposed.

The passivation layer 206 may be used for electrical passivation. The passivation layer 206 may remain along the first and second mesa surface 210, 211, to play a role of preventing an electrical short of a metal reflectance film 209 and the n-type semiconductor layer 202 and an electrical short of the metal reflectance film 209 and the p-type semiconductor layer 204 that will be explained hereinafter.

Then, a p-electrode 207 and an n-electrode 208 are formed. The p-electrode 207 comes in contact with the transparent conductive layer 205 exposed through the passivation layer 206 etching process. The n-electrode 208 comes in contact with the n-type semiconductor layer 202 exposed through the passivation layer 206 etching process. Herein, any electrode material generally known in the related field may be used, and any generally known method in the related field may be used. Then, heating may be performed to form an ohmic contact of the n-electrode 208.

The metal reflectance film 209 is coated on the surface of the first and second mesa surface 210, 211 to which the passivation layer 206 for preventing an electrical short is applied. The forward mesa shape can be helpful for the metal reflectance film 209 to be laminated on the first and second mesa surface 210, 211.

The laminated thickness of the metal reflectance film 209 must be thicker than the optical skin depth of the metal reflectance film 209 regarding the wavelength of the LED. The metal reflectance film 209 may be made of a metal material having a big reflectance ratio to the wavelength of the LED to be formed, for example Au, Al, and Ag. The metal reflectance film 209 may re-reflect the light escaping from the first and second mesa surface 210, 211, thereby increasing the light extraction efficiency of the LED.

Herein, the material used for the p-electrode 207, n-electrode 208, and metal reflectance film 209 may be the same as in FIG. 1.

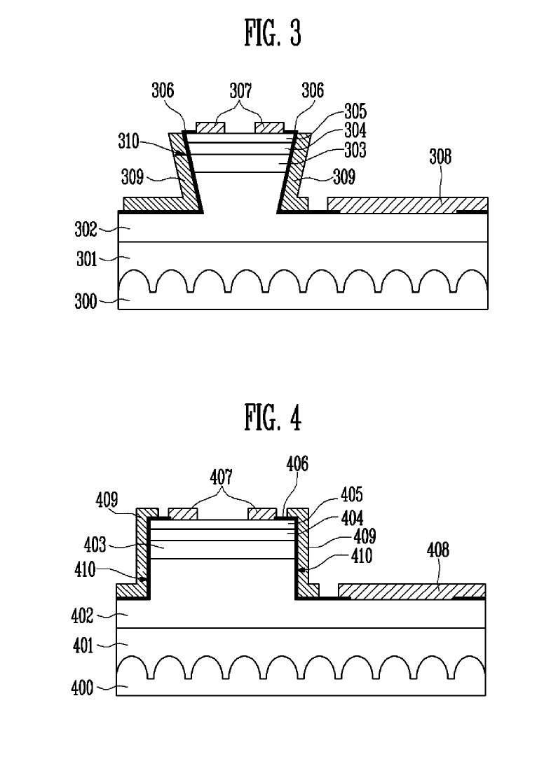

FIG. 3 is a cross-sectional view illustrating an LED according to another embodiment of the present invention. Hereinbelow, for convenience of explanation, explanation is omitted for the same components as those illustrated in FIG. 1.

Referring to FIG. 3, an LED includes a buffer layer 301 formed on a substrate 300, an n-type semiconductor layer 302 laminated on the buffer layer 301, an active layer 303 grown on the n-type semiconductor layer 302, a p-type semiconductor layer 304 grown on the active layer 303, and a transparent conductive layer 305 formed on the p-type semiconductor layer 304. The substrate 300, buffer layer 301, n-type semiconductor layer 302, active layer 303, p-type semiconductor layer 304, and transparent conductive layer 305 may be made of a same material and in a same method as described with reference to FIG. 1.

The transparent conductive layer 305, p-type semiconductor layer 304, active layer 303, and n-type semiconductor layer 302 of a partial thickness are etched to have a reverse mesa shape. Thus, unlike in FIG. 1, a side wall of the etched structure has a first mesa surface 310 of a reverse mesa shape. As the side wall of the etched structure is formed in the reverse mesa shape, the width of the etched structure gets narrower as it gets to the lower portion thereof.

The first mesa surface 310 of the reverse mesa shape may be formed in an ICP-RIE (inductively coupled plasma-reactive ion etching) method using an etching mask made of Ni, and an etching gas including Cl₂ and Ar or an etching gas including Cl₂ and BCl₃. Under the aforementioned conditions, the inclination angle of the first mesa surface 310 may be controlled to be 70°. Herein, the inclination angle of the first mesa surface 310 of the reverse mesa shape may be controlled by increasing the pressure of an etching equipment and reducing a bias power.

A passivation layer 306 for preventing an electrical short is formed along the surface of the entire structure where the first mesa surface 310 of a reverse mesa shape is formed and then etched. The etching area and forming material of the passivation layer 306 are as described with reference to FIG. 1. Then, as illustrated in FIG. 1, a p-electrode 307 and n-electrode 308 are formed.

Then, a metal reflectance film 309 is coated on the surface of the first mesa surface 310 to which the passivation layer 306 is applied. As illustrated in FIG. 1, the metal reflectance film 309 is made of a material having a high reflectance ratio to the wavelength of the LED to be formed, and is formed in a greater thickness than the optical skin depth regarding the wavelength of the LED to be formed. In this case, the light penetrating the first mesa surface 310 may be re-reflected by the metal reflectance film 309 thereby increasing the light extraction efficiency.

The metal reflectance film 309 may be laminated using an e-beam evaporator. In this case, due to the verticality of the laminating process, the first mesa surface 310 of the reverse mesa shape may cause a shadowing effect. In order to overcome such a shadowing effect and enable easy laminating of the metal reflectance film 309 on the first mesa surface 310, the metal reflectance film 309 may be laminated while tilting or rotating the specimen.

FIG. 4 is a cross-sectional view illustrating an LED according to another embodiment of the present invention.

Hereinbelow, for convenience of explanation, explanation is omitted for the same components as those illustrated in FIG. 1.

Referring to FIG. 4, an LED includes a buffer layer 401 formed on a substrate 400, an n-type semiconductor layer 402 laminated on the buffer layer 401, an active layer 403 grown on the n-type semiconductor layer 402, a p-type semiconductor layer 404 grown on the active layer 403, and a transparent conductive layer 405 formed on the p-type semiconductor layer 404. The substrate 400, buffer layer 401, n-type semiconductor layer 402, active layer 403, p-type semiconductor layer 404, and transparent conductive layer 405 may be made of a same material and in a same method as described with reference to FIG. 1.

The transparent conductive layer 405, p-type semiconductor layer 404, active layer 403, and n-type semiconductor layer 402 of a partial thickness are etched to have a vertical mesa shape. Thus, unlike in FIG. 1, a side wall of the etched structure has a first mesa surface 410 of a vertical mesa shape.

The first mesa surface 410 of a vertical mesa shape may be formed in an ICP-RIE (inductively coupled plasma-reactive ion etching) method using an etching mask made of a material having a great etching selection ratio to the p-type semiconductor layer 404, active layer 403, and n-type semiconductor layer 402. For example, a material that satisfies the condition of the etching selection ratio of the etching mask to GaN being 5:1 may be used as an etching mask. Besides such a material, Cr or a metal capable of exerting a similar function thereto may be used. Besides these, SiO₂ or SiₓN_{y} (x,y are natural numbers) may be used as material for the etching mask, and a first mesa surface 410 close to verticality of 70° or more may be formed by performing an etching process using an RIE (reactive ion etching) method having improved verticality. Herein, the etching selection ratio to GaN may be increased by improving the mask etching inclination and density of SiO₂ or SiₓN_{y} (x,y are natural numbers), without increasing the thickness of SiO₂ or SiₓN_{y} (x,y are natural numbers).

Along the surface of the entire structure where the vertical first mesa surface 410 is formed, a passivation layer 406 for preventing an electrical short is formed and then etched. The etching area and forming material of the passivation layer 406 are as described with reference to FIG. 1. Then, a p-electrode 407 and n-electrode 408 are formed as described with reference to FIG. 1.

Then, on the surface of the first mesa surface 410 to which the passivation layer 406 is applied, a metal reflectance film 409 is laminated. As illustrated in FIG. 1, the metal reflectance film 409 is made a material having a high reflectance ratio to the wavelength of an LED to be formed, and in a greater thickness than the optical skin depth regarding the wavelength of the LED to be formed. In such a case, the light that penetrates the first mesa surface 410 may be re-reflected by the metal reflectance film 409 thereby increasing the light extraction efficiency.

The metal reflectance film 409 may be laminated using an e-beam evaporator. In such a case, due to the verticality of the laminating process, the first mesa surface 410 of a vertical mesa shape may cause a shadowing effect. In order to overcome such a shadowing effect and enable easy laminating of the metal reflectance film 409 on the first mesa surface 410, the metal reflectance film 409 may be laminated while tilting or rotating the specimen.

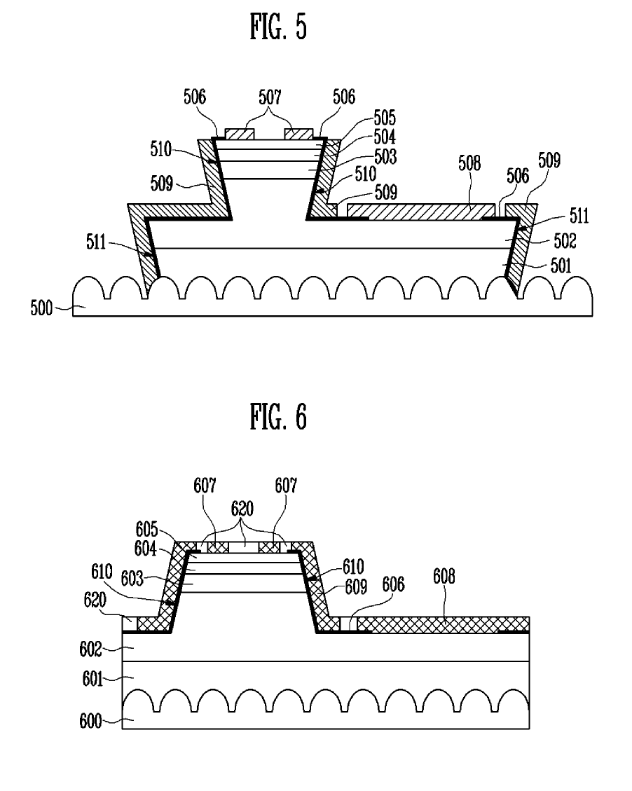

FIG. 5 is a cross-sectional view illustrating an LED according to another embodiment of the present invention.

Referring to FIG. 5, an LED includes a buffer layer 501 formed on a substrate 500, an n-type semiconductor layer 502 laminated on the buffer layer 501, an active layer 503 grown on the n-type semiconductor layer 502, a p-type semiconductor layer 504 grown on the active layer 503, and a transparent conductive layer 505 formed on the p-type semiconductor layer 504. The substrate 500, buffer layer 501, n-type semiconductor layer 502, active layer 503, p-type semiconductor layer 504, and transparent conductive layer 505 may be made of a same material and in a same method as described with reference to FIG. 1.

The transparent conductive layer 505, p-type semiconductor layer 504, active layer 503, and n-type semiconductor layer 502 of a partial thickness are etched such that the etched structure has a reverse mesa shape. The etching process for forming a reverse mesa shape is the same as described with reference to FIG. 3. A side wall of the structure etched through the etching process described with reference to FIG. 3 has a first mesa surface 510 of a reverse mesa shape.

Then, a partial thickness of the n-type semiconductor layer 502 and buffer layer 501 that remain in a lower portion of the first mesa surface 510 is etched, thereby exposing the substrate 500. Herein, the side wall of the structure etched in the same manner as described with reference to FIG. 3 is etched to have a second mesa surface 511 of a reverse mesa shape.

Along the surface of the entire structure where the first and second mesa surface 510, 511 are formed, a passivation layer 506 for preventing an electrical short is formed and then etched. The etching area and forming material of the passivation layer 506 are as described with reference to FIG. 1. Then, as described with reference to FIG. 1, a p-electrode 507 and n-electrode 508 are formed.

Then, on the surface of the first and second mesa surface 510, 511 to which the passivation layer 506 is applied, a metal reflectance film 509 is laminated. As described with reference to FIG. 1, the metal reflectance film 509 is made of a material having a high reflectance ratio to the wavelength of the LED to be formed, and in a thickness greater than the optical skin depth regarding the wavelength of the LED to be formed. In this case, the light that penetrates the first and second mesa surface 510, 511 may be re-reflected by the metal reflectance film 509 thereby increasing the light extraction efficiency.

FIG. 6 is a cross-sectional view illustrating an LED according to another embodiment of the present invention. Hereinbelow, for convenience of explanation, explanation is omitted for the same components as those illustrated in FIG. 1.

Referring to FIG. 6, an LED includes a buffer layer 601 formed on a substrate 600, an n-type semiconductor layer 602 laminated on the buffer layer 601, an active layer 603 grown on the n-type semiconductor layer 602, a p-type semiconductor layer 604 grown on the active layer 603, and a transparent conductive layer 605 formed on the p-type semiconductor layer 604. The substrate 600, buffer layer 601, n-type semiconductor layer 602, active layer 603, p-type semiconductor layer 604, and transparent conductive layer 605 may be made of a same material and in a same method as described with reference to FIG. 1.

The transparent conductive layer 605, p-type semiconductor layer 604, active layer 603, and n-type semiconductor layer 602 of a partial thickness are etched to have a forward mesa shape using the etching process described with reference to FIG. 1. Thus, a side wall of the structure etched through the etching process described with reference to FIG. 1 has a first mesa surface 610 of a forward mesa shape.

Along the surface of the entire structure where the first mesa surface 610 of a forward mesa shape is formed, a passivation layer 606 is formed for preventing an electrical short and then etched. The etching area and forming material of the passivation layer 606 are as described with reference to FIG. 1.

Then, along the surface of the entire structure, a photoresist film is laminated, and a partial area of the photoresist film is removed to form a photoresist pattern 620. The removed area of the photoresist film is an area where a p-electrode 607, n-electrode 608, and metal reflectance film 609 are to be formed. More specifically, a partial area of the photoresist film is removed such that the passivation layer 606 formed along the transparent conductive layer 605, n-type semiconductor layer 602, and first mesa surface 610 is exposed by a photoresist pattern 620.

Then, the areas from which the photoresist film is removed are filled with a conductive material, thereby forming a p-electrode 607, n-electrode 608, and metal reflectance film 609 at the same time. Herein, the reflectance metal described with reference to FIG. 1 may be used as the conductive material. The process of forming the p-electrode 607, n-electrode 608, and metal reflectance film 609 may be applied to form the structures of FIGS. 2 to 5. When using the process described with reference to FIG. 6, the process may be further simplified.

Herein, when filling the areas from which the photoresist film is removed with the conductive material, the conductive material may be formed in unwanted areas. In such a case, it is possible to further perform a process of removing a portion of the conductive material formed on the unwanted areas such as an upper portion of the photoresist pattern 620 and so forth. Herein, when the thickness of the photoresist pattern 620 is formed to be greater than that of the conductive material, it is possible to increase the shadowing effect caused by the photoresist pattern 620, thereby easily removing the conductive material formed on the unwanted areas. Thus, the p-electrode 607, n-electrode 608, and metal reflectance film 609 may be easily formed on wanted areas.

Each of the first and second mesa surface described with reference to FIGS. 1 to 6 is not limited to the aforementioned embodiments, but may be formed in any one mesa shape selected from the forward mesa shape, reverse mesa shape, and vertical mesa shape.

The aforementioned embodiments of the present invention may form an LED side wall in a mesa shape to not only re-reflect the light reflected to the LED side wall, but to also form a metal reflectance film on the LED side wall, thereby increasing the re-reflecting efficiency on the LED side wall. Thus the light extraction efficiency of the LED may be increased.

Meanwhile, there is also a method of coating an etching surface where a forward mesa or vertical mesa is formed with a DBR (Distributed Bragg Reflector) using a dielectric material such that light does not escape to the etched mesa surface thereby increasing the light extraction efficiency. However, such a method is disadvantageous in that if the designing thickness of the DBR is not strictly guaranteed, the reflectance ratio would decrease, making it difficult to restrict the escaping light. On the other hand, embodiments of the present invention maximize the light reflectance ratio on an etched mesa surface using a metal reflectance film, thereby efficiently restricting the escaping light.

In the drawings and specification, there have been disclosed typical exemplary embodiments of the invention, and although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A light emitting device comprising:
a buffer layer formed on a substrate;
an n-type semiconductor layer formed on the buffer;
an active layer formed on a partial area of the n-type semiconductor layer such that the n-type semiconductor layer is exposed;
a p-type semiconductor layer formed on the active layer;
a transparent conductive layer formed on the p-type semiconductor layer;
a first mesa surface formed along a side wall of the active layer from a side wall of the transparent conductive layer;
a passivation layer formed along the first mesa surface; and
a metal reflectance film formed along the passivation layer such that it re-reflects escaping light.

2. The device according to claim 1,
wherein the first mesa surface is formed in any one of a forward mesa shape, reverse mesa shape, and vertical mesa shape.

3. The device according to claim 1,
wherein the buffer layer and the n-type semiconductor layer are formed on a partial area of the substrate, and comprises a side wall consisting of a second mesa surface.

4. The device according to claim 3,
wherein the second mesa surface is formed in any one of a forward mesa shape, reverse mesa shape, and vertical mesa shape.

5. The device according to claim 3,
wherein the passivation layer and the metal reflectance film are further formed along the second mesa surface.

6. The device according to claim 1,
further comprising:
an n-electrode contacting the n-type semiconductor layer; and
a p-electrode contacting the transparent conductive layer.

7. The device according to claim 6,
wherein the n-electrode and the p-electrode are made of a same material as the metal reflectance film.

8. A method for fabricating a light emitting device, the method comprising:
laminating a buffer layer, n-type semiconductor layer, active layer, p-type semiconductor layer, and transparent conductive layer on a substrate successively;
forming a first mesa surface by etching the transparent conductive layer, the p-type semiconductor layer, the active layer, and a partial thickness of the n-type semiconductor layer such that the n-type semiconductor layer is exposed;
forming a passivation layer along the first mesa surface; and
forming a metal reflectance film configured to re-reflect escaping light along the passivation layer.

9. The method according to claim 8,
wherein the forming a first mesa surface is performed by a forward mesa etching process using an etching mask made of any one of a photoresist, SiO₂, and SiₓN_{y} (x,y are natural numbers).

10. The method according to claim 8,
wherein the forming a first mesa surface comprises forming a reverse mesa in an ICP-RIE (inductively coupled plasma-reactive ion etching) method using an etching mask made of Ni, and an etching gas including Cl₂ and Ar or an etching gas including Cl₂ and BCl₃.

11. The method according to claim 8,
wherein the forming a first mesa surface comprises forming a vertical mesa in an ICP-RIE (inductively coupled plasma-reactive ion etching) method using an etching mask made of Cr.

12. The method according to claim 8,
further comprising forming a second mesa surface by etching the n-type semiconductor layer and the buffer layer such that the substrate is exposed,
wherein at the forming a passivation layer and a metal reflectance film, the passivation layer and the metal reflectance film are further formed along the second mesa surface.

13. The method according to claim 12,
wherein the forming a second mesa surface is performed in a forward mesa etching process using an etching mask made of any one of a photoresist, SiO₂, and SiₓN_{y} (x,y are natural numbers).

14. The method according to claim 12,
wherein the forming a second mesa surface comprises forming a reverse mesa in an ICP-RIE (inductively coupled plasma-reactive ion etching) method using an etching mask made of Ni, and an etching gas including Cl₂ and Ar or an etching gas including Cl₂ and BCl₃.

15. The method according to claim 12,
wherein the forming a second mesa surface comprises forming a vertical mesa in an ICP-RIE (inductively coupled plasma-reactive ion etching) method using an etching mask made of Cr.

16. The method according to claim 8,
further comprising forming an n-electrode contacting the n-type semiconductor layer and a p-electrode contacting the transparent conductive layer.

17. The method according to claim 16,
wherein the forming an n-electrode and p-electrode is performed separately from the forming of a metal reflectance film.

18. The method according to claim 16,
wherein the forming an n-electrode and p-electrode is performed at the same time of the forming of a metal reflectance film.

19. The method according to claim 18,
wherein the forming a metal reflectance film, n-electrode and p-electrode comprises
forming a photoresist film on an upper portion of an entire structure where the passivation layer is formed;
forming a photoresist pattern that opens the passivation layer, transparent conductive layer, and n-type semiconductor layer by etching the photoresist layer; and
filling an area where the photoresist film is etched with a conductive material.
